(19) United States
(12) Patent Application Publication
(10) Pub. No.: US 2009/0127622 A1
(43) Pub. Date: May 21, 2009

(54) TRANSPARENT THIN-FILM TRANSISTOR AND MANUFACTURING METHOD OF THE TRANSISTOR

(76) Inventor: Ju-Il Song, Daegu (KR)

Correspondence Address: SHERR & VAUGHN, PLLC, 620 HERNDON PARKWAY, SUITE 200, HERNDON, VA, 20170, US

(21) Appl. No.: 12/271,844

(22) Filed: Nov. 15, 2008

(30) Foreign Application Priority Data
Nov. 16, 2007 (KR) 10-2007-0117024

(51) Int. Cl. H01L 29/786; H01L 21/336

(52) U.S. Cl. 257/347; 438/158; 257/E29.273; 257/E21.411

(57) ABSTRACT

A transparent thin-film transistor and a method of manufacturing the same includes a substrate composed of a transparent material, and a gate electrode, a gate dielectric layer, an activation layer, and source and drain electrodes, at least one of each being composed of an amorphous oxide material.

The present application claims priority under 35 U.S.C. §119 to Korean Patent Application No. 10-2007-0117024 (filed on Nov. 16, 2007), which is hereby incorporated by reference in its entirety.

### BACKGROUND

A transistor for a driving circuit of an image display apparatus such as a liquid crystal display (LCD) may be formed within the degree in which the progress path of light is not interrupted, such that there are many limitations in the formation and arrangement of the circuit. For example, in the case of a non-transparent amorphous silicon type thin-film transistor (TFT), a transistor formed as a driving circuit must be located in a region outside the light path. The transistor must also be formed of a size such that it is not affected while light generated from a backlight unit is transferred to a liquid crystal panel. Therefore, problems arise in that there is a limitation in minimizing the size of the image display apparatus and diverse forms of transistor products cannot be used.

In such a view, a study on a transparent thin-film transistor (TTFT) has been progressed. In a transparent thin-film transistor, a transparent electrode may be formed using an oxide such as indium oxide, indium tin oxide (ITO), tin oxide, zinc oxide, or the like. Alternatively, an organic transparent electrode may be formed by injecting additives into an organic material, for example, a conductive polymer such as pentacene, PEDOT [poly(3,4-ethylnenedioxythiophene)] or the like. However, when the transparent thin-film transistor uses such an oxide, it needs a high temperature annealing process, which in turn, causes problems of a limitation in material. Meaning, the transparent thin-film transistor cannot be manufactured in a flexible substrate type, and also increases the overall manufacturing costs. When the transparent thin-film transistor uses organic materials, the transparent thin-film transistor is sensitive to the effects of moisture and foreign material. Accordingly, the physical properties of the transparent thin-film transistor is deteriorated easily due to the external factors. Therefore, problems arise in that the process is complicated and production yield is reduced. When the transparent thin-film transistor uses an oxide and/or an organic material, problems arise in that a defect is likely to generate on a thin-film interface easily and interface resistance increases. In particular, since there is a limitation in improving the transmittance, a problem still arise in that the optical efficiency of the image display apparatus is deteriorated.

### SUMMARY

Embodiments relate to a transparent thin-film transistor and a manufacturing method of the transistor that maximizes optical efficiency by forming each semiconductor layer using an amorphous transparent conductor.

Embodiments relate to a transparent thin-film transistor and a manufacturing method of the transistor that maximizes the electrical property and the light transmittance by reducing interface defects and resistance.

Embodiments relate to a transparent thin-film transistor and a manufacturing method of the transistor that does not require a high-temperature annealing process.

Embodiments relate to a transparent thin-film transistor that may include at least one of the following: a substrate composed of transparent material; a gate electrode formed on and/or over the substrate; a gate dielectric layer formed on and/or over the gate electrode and the substrate; an activation layer formed on and/or over the gate dielectric layer; and a source electrode and a drain electrode spaced from each other on and/or over the activation layer so that a channel region is formed. In accordance with embodiments, at least one layer of the gate electrode, the gate dielectric layer, the activation layer, the source electrode and the drain electrode is amorphous oxide.

Embodiments relate to a transparent thin-film transistor that may include at least one of the following: a substrate composed of transparent material; a gate electrode formed over the substrate; a gate dielectric layer formed over the gate electrode and the substrate; an activation layer formed over the gate dielectric layer; and a source electrode and a drain electrode formed spaced from each other over the activation layer to define a channel region. In accordance with embodiments, at least one layer of the gate electrode, the gate dielectric layer, the activation layer, the source electrode and the drain electrode is composed of an amorphous oxide material.

Embodiments relate to a method of manufacturing a transparent thin-film transistor that may include at least one of the following: forming a gate electrode on and/or over a substrate of transparent material; forming a gate dielectric layer on and/or over the gate electrode and the substrate with including at least a portion of the gate electrode; forming an activation layer on and/or over the gate dielectric layer; and forming a source drain and a drain electrode spaced from each other on the activation layer. In accordance with embodiments, at least one layer of the gate electrode, the gate dielectric layer, the activation layer, the source electrode and the drain electrode is amorphous oxide.

Embodiments relate to a method that may include at least one of the following: forming a gate electrode over a substrate composed of transparent material; and then forming a gate dielectric layer over the gate electrode and the substrate; and then forming an activation layer over the gate dielectric layer; and then simultaneously forming a source drain and a drain electrode spaced from each other over the activation layer to define a channel region. In accordance with embodiments, at least one layer of the gate electrode, the gate dielectric layer, the activation layer, the source electrode and the drain electrode is composed of an amorphous oxide material.

Embodiments relate to a method that may include at least one of the following: providing a substrate composed of a transparent material; and then forming a gate electrode composed of an amorphous material over the substrate; and then forming a gate dielectric layer composed of an amorphous material over the uppermost surface and sidewalls of the gate electrode; and then forming an activation layer composed of an amorphous material over the gate dielectric layer; and then simultaneously forming a source electrode composed of an amorphous material and a drain electrode composed of an amorphous material spaced apart over the activation layer to define a channel region.

### DRAWINGS

Example FIGS. 1 and 2 illustrate a transparent thin-film transistor in accordance with embodiments.

Example FIG. 3 is a graph showing the measured transmittance of a transparent thin-film transistor in accordance with embodiments.

FIG. 4 is a graph showing the measured current-voltage property of a transparent thin-film transistor in accordance with embodiments.

FIG. 5 is a graph showing the electrical property between electrodes of a transparent thin-film transistor in accordance with embodiments.

### DESCRIPTION

Example FIG. 1 is a schematic upper surface view showing a configuration of a transparent thin-film transistor 100 and example FIG. 2 is a side cross-sectional view showing a configuration of a transparent thin-film transistor 100 at cross-section “A” of example FIG. 1

Referring to example FIGS. 1 and 2, the transparent thin-film transistor 100 includes a substrate 110, a gate electrode 120, a gate dielectric layer 130, an activation layer 140, a source electrode 150 and a drain electrode 160. The gate electrode 120 is formed on and/or over the substrate 110. The substrate 110 is made of a transparent material. The substrate 110 may be a glass substrate. Micro structure and properties of a thin film layer deposited on and/or over the substrate 110 are affected greatly by organic material existing on and/or over a surface of the substrate 110, such that a cleaning process is performed on and/or over the substrate 110 before the gate electrode 120 is formed. In order to remove the organic material, acetone, ethyl alcohol, and deionized water are applied sequentially to perform an ultra-sonic cleansing on and/or over the surface of the substrate 110 for a time period of fifteen minutes per cleansing. Thereafter, moisture and foreign material remaining on and/or over the substrate 110 are removed using N₂ gas.

The gate electrode 120, gate dielectric layer 130, activation layer 140, source drain 150 and drain electrode 160 are deposited using amorphous oxide such as AlOₓ based aluminum oxide and/or zinc indium oxide (ZIO). The amorphous oxide can be formed as a film at normal temperature, such that the respective layers for forming the gate electrode 120, gate dielectric layer 130, activation layer 140, source drain 150 and drain electrode 160 may be deposited at normal temperature using a RF sputtering method. The respective layers for forming the gate electrode 120, gate dielectric layer 130, activation layer 140, source drain 150 and drain electrode 160 may also be deposited using a thin-film deposition technique such as an Atmospheric Pressure Chemical Vapor Deposition (APCVD), a Lower Pressure Chemical Vapor Deposition (LPCVD), a Plasma Enhanced Chemical Vapor Deposition (PECVD) or the like. An initial degree of vacuum within a sputtering chamber is maintained at 1×10⁻⁶ to 1×10⁻⁴ Torr, and a pre-sputtering is performed for about 30 minutes in order to remove foreign material from a surface of a target before the gate electrode 120 is deposited.

In accordance with embodiments, the gate electrode 120 is formed at a thickness of about 800 to 1200 Å using ZIO deposited and applying a voltage of about 40 W to 60 W. Thereafter, the gate dielectric layer 130 is formed on and/or over the substrate 110 including at least a portion of the gate electrode 120. The gate dielectric 130 may be formed on an uppermost surface and sidewalls of the gate electrode 120. In accordance with embodiments, the gate dielectric layer 130 is made of an aluminum oxide film and is formed at thickness of about 800 to 1200 Å and applying a voltage of about 90 W to 1100 W. In particular, since the thickness of the gate dielectric layer 130 on and/or over the gate electrode 120 has a correlation with saturation current, it is preferable to be formed thinner than the activation layer 140. The activation layer 140 is formed on and/or over the gate dielectric layer 130 at a thickness of 400 to 800 Å using ZIO and applying a voltage of about 40 W to 60 W during the deposition. The activation layer 140 is deposited in an oxygen and argon atmosphere such that an oxygen partial pressure is controlled so that the semiconductor property may be revealed.

The activation layer 140, gate electrode 120, source electrode 150, and drain electrode 160 are made of an amorphous material that can be formed at normal temperature. In accordance with embodiments, the activation layer 140, gate electrode 120, source electrode 150, and drain electrode 160 are made in the same composition in order to maximize current mobility. While the activation layer 140, gate electrode 120, source electrode 150 and drain electrode 160 are formed using ZIO, embodiments are not limited thereto.

Next, the source electrode 150 and drain electrode 160 are formed spaced apart on and/or over the activation layer 140 to define a channel region. In a state where voltage of 40 W to 60 W is applied, ZIO material is sputtered to be deposited on and/or over an uppermost surface of the activation layer 140, such that the source electrode 15 and drain electrode 160 are formed. For example, the source electrode 150 and drain electrode 160 may be formed at a thickness of about 800 to 1200 Å. The gate electrode 120, gate dielectric layer 130, activation layer 140, source electrode 150 and drain electrode 160 may be deposited using a photoresist film of which deposition region is opened, and the processes of coating, depositing and removing of the photoresist film may be progressed repeatedly whenever the respective layers for forming the gate electrode 120, gate dielectric layer 130, activation layer 140, source drain 150 and drain electrode 160 are deposited.

As described above, the transparent thin-film transistor 100 in accordance with embodiments may reduce defects between interfaces and resistance components greatly, since the gate electrode 120, gate dielectric layer 130, activation layer 140, source drain 150 and drain electrode 160 are made of amorphous materials.

Compared with other transparent thin-film transistors formed of ITO, which needs a crystallization process in order to reveal an electrode property, the transparent thin-film transistor 100 in accordance with embodiments has an excellent effect. In particular, the gate electrode 120, gate dielectric layer 130, activation layer 140, source drain 150 and drain electrode 160 which form the transparent thin-film transistor 100 have transmittance of greater than 80%, making it possible to maximize aperture ratio and optical efficiency. Therefore, when a driving circuit is formed for a liquid crystal display or the like, there is no limitation in disposing devices in consideration of a light path. If the transparent thin-film transistor 100 in accordance with embodiments is used, the degree of freedom can be secured in designing the circuit and the circuit size can be reduced. Also, since the deposition process can be processed at normal temperature, the transparent thin-film transistor 100 in accordance with embodiments can be implemented on a flexible circuit board.

Example FIG. 3 is a graph showing the measured transmittance of a transparent thin-film transistor 100 in accordance with embodiments, wherein the X axis represents a wavelength band nm of light incident on the transparent thin-film transistor 100 and the Y axis represents the transmittance using %. Also, a measurement line indicated by a solid line represents a case where the transmittance is measured after a gate electrode 120 is formed, a measurement line indicated by a bold dotted line represents a case where the transmittance is measured after a gate dielectric layer 130 is formed, and a measurement line indicated by a thin dotted line represents a case where the transmittance is measured after a source electrode 150 and a drain electrode 160 are formed. The numerical value shown in example FIG. 3 is a numerical value measured using “UV-visible spectrophotometer”, and the range of wavelength band for each thin film on and/or over the substrate is set as 250 to 900 nm. As a result of the measurement, since the total transmittance in the wavelength band of about 350 nm to 500 nm, that is, in a visible ray region, is about 75%, it can be known that the transparent thin-film transistor 100 has an excellent transmittance and the stack of the gate electrode 120, gate dielectric layer 130, activation layer 140, source drain 150 and drain electrode 160 does not affect greatly to the transmittance.

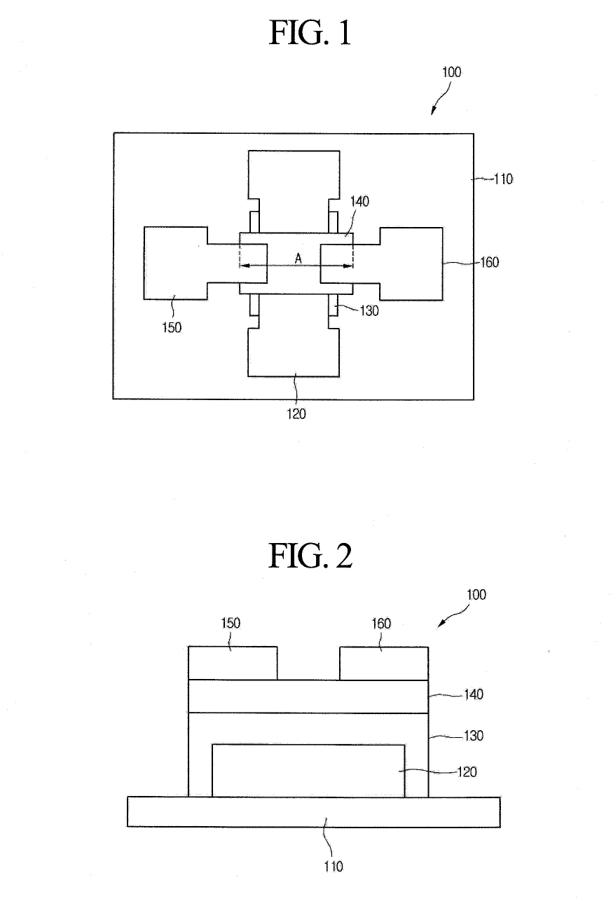

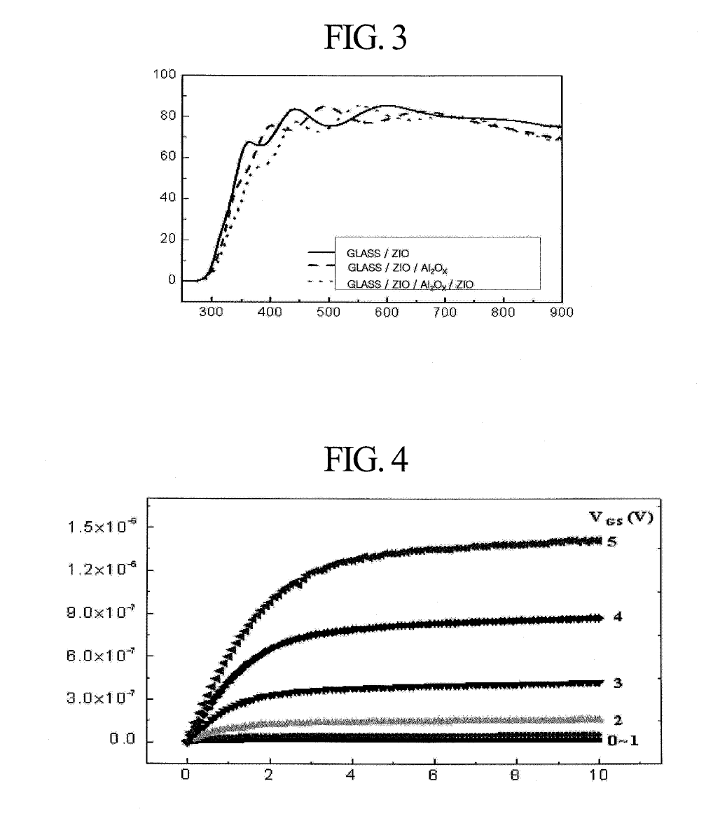

Example FIG. 4 is a graph showing the measured current-voltage property of a transparent thin-film transistor 100 according to the embodiment of the present invention, wherein the X axis represents drain voltage VDS and V and the Y axis represents drain current IDS and A. In the graph shown in example FIG. 4, the drain voltage of 0V to 10V is applied (X axis), and five indication lines represent the change of the drain current (Y axis) when the gate voltage of 0V to 5V is applied in 1V unit. Referring to example FIG. 4, it is known that as the gate voltage is increased, the drain current enters to a saturation state from a low-voltage state of about 5V, and at this time, the saturation current is measured as about 1.41 μA. As a result of the measurement, it is known that the transparent thin-film transistor is in a driving state corresponding to na n-channel TFT to have an excellent operating property.

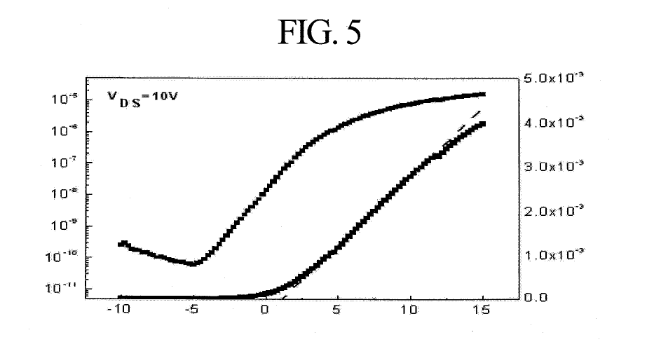

Example FIG. 5 is a graph showing the electrical property between electrodes of a transparent thin-film transistor 100 in accordance with embodiments. In the graph of example FIG. 5, the X axis represents gate voltage V_{GS} and left-Y axis represents drain current I_{DS}. Also, right-Y axis represents the drain current in log scale. The graph of example FIG. 5 shows that when the drain voltage V_{DS} is maintained as 10V and the gate voltage is changed, the drain current accordingly thereof is measured. As a result of data analysis with reference to example FIG. 5, a pinch-off phenomenon is observed and a ratio of turn on/turn off of the transparent thin-film transistor 100 in accordance with embodiments is calculated to be about 2.7×10⁵. The threshold voltage is about 1.1V and channel mobility which generates a field effect is measured as 0.53 cm²/Vs.

The following effects can be obtained by a transparent thin-film transistor and manufacturing method of the transistor in accordance with embodiments described above. Firstly, the respective semiconductor layers are formed using an amorphous transparent conductive material that can be formed as a film at normal temperature, making it possible to implement transmittance of more than 75% in a visible ray region. Moreover, the electrical properties are maximized, making it possible to implement a high field-effect and a channel mobility. Secondly, the driving circuit of the image display apparatus may be made using the transparent thin-film transistor having excellent operating property and light transmittance, making it possible to facilitate the implementation of the circuit and secure the degree of freedom in designing the circuit and thus to contribute to the development of display industries including a liquid crystal display (LCD). Thirdly, an annealing process is not required, making it possible to implement a transistor device on the substrate of diverse materials, reduce a manufacturing cost and improve process efficiency.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A transparent thin-film transistor comprising:
a substrate composed of transparent material;
a gate electrode formed over the substrate;
a gate dielectric layer formed over the gate electrode and the substrate;
an activation layer formed over the gate dielectric layer; and
a source electrode and a drain electrode formed spaced from each other over the activation layer to define a channel region,
wherein at least one layer of the gate electrode, the gate dielectric layer, the activation layer, the source electrode and the drain electrode is composed of an amorphous oxide material.

2. The transparent thin-film transistor of claim 1, wherein the gate electrode has a thickness of 800 to 1200 Å.

3. The transparent thin-film transistor of claim 1, wherein the amorphous oxide material comprises at least one of amorphous zinc indium oxide (ZIO) and amorphous aluminum oxide.

4. The transparent thin-film transistor of claim 1, wherein the substrate is a glass substrate.

5. The transparent thin-film transistor of claim 1, wherein the gate electrode, the activation layer, the source electrode and the drain electrode are made of the same amorphous oxide that can be formed as a film at normal temperature.

6. The transparent thin-film transistor of claim 1, wherein the thickness of the gate dielectric layer is less than that of the activation layer.

7. A method comprising:
forming a gate electrode over a substrate composed of a transparent material; and then
forming a gate dielectric layer over the gate electrode and the substrate; and then
forming an activation layer over the gate dielectric layer; and then
simultaneously forming a source electrode and a drain electrode spaced from each other over the activation layer to define a channel region,
wherein at least one layer of the gate electrode, the gate dielectric layer, the activation layer, the source electrode and the drain electrode is composed of an amorphous oxide material.

8. The method of claim 7, wherein the amorphous oxide material comprises at least one of amorphous zinc indium oxide (ZIO) and amorphous aluminum oxide.

9. The method of claim 7, wherein forming of the gate electrode comprises:
performing a first cleaning process to remove organic material from the surface of the substrate; and then
performing a second cleaning process to remove moisture and foreign material remaining on the surface of the substrate; and then
forming the gate electrode after performing the first and second cleaning processes.

10. The method of claim 9, wherein performing the first cleaning process:
performing a first ultra-sonic cleansing of the surface of the substrate using acetone; and then
performing a second ultra-sonic cleansing of the surface of the substrate using ethyl alcohol; and then
performing a third ultra-sonic cleansing of the surface of the substrate using deionized water.

11. The method of claim 9, wherein performing the second cleaning process comprises applying N₂ gas.

12. The method of claim 7, wherein at least one layer of the gate electrode, the gate dielectric layer, the activation layer, the source electrode and the drain electrode is deposited using a RF sputtering method at normal temperature.

13. The method of claim 12, further comprising, before forming the gate electrode, performing a pre-sputtering process.

14. The method of claim 7, wherein the activation layer is deposited in an oxygen and argon atmosphere using a RF sputtering method.

15. The method of claim 14, wherein forming the activation layer comprises controlling the partial pressure of the oxygen.

16. The method of claim 7, wherein at least one of the gate electrode, the gate dielectric layer, the source electrode and the drain electrode is formed at a thickness of 800 to 1200 Å.

17. The method of claim 16, wherein the activation layer is formed at a thickness of 400 to 800 Å.

18. The method of claim 17, wherein the gate dielectric layer is formed at a thickness less than that of the activation layer.

19. A method comprising:
providing a substrate composed of a transparent material; and then
forming a gate electrode composed of an amorphous material over the substrate; and then
forming a gate dielectric layer composed of an amorphous material over the uppermost surface and sidewalls of the gate electrode; and then
forming an activation layer composed of an amorphous material over the gate dielectric layer; and then
simultaneously forming a source electrode composed of an amorphous material and a drain electrode composed of an amorphous material spaced apart over the activation layer to define a channel region.

20. The method of claim 19, wherein the amorphous material comprises at least one of amorphous zinc indium oxide (ZIO) and amorphous aluminum oxide.
